(19) United States
(12) Patent Application Publication
(10) Pub. No.: US 2010/0283045 A1
(43) Pub. Date: Nov. 11, 2010

(54) ORGANIC ELECTROLUMINESCENT ELEMENT

(76) Inventor: Hideki Uchida, Osaka (JP)

Correspondence Address: NIXON & VANDERHYE, PC, 901 NORTH GLEBE ROAD, 11TH FLOOR, ARLINGTON, VA, 22203, US

(21) Appl. No.: 12/811,058

(22) PCT Filed: Aug. 28, 2008
(86) PCT No.: PCT/JP2008/065418

§ 371 Date: Jun. 28, 2010

(30) Foreign Application Priority Data
Dec. 28, 2007 (JP) 2007-340311

(51) Int. Cl. H01L 51/50; H01L 51/54

(52) U.S. Cl. 257/40; 257/E51.019; 257/E51.027; 257/79; 977/773

(57) ABSTRACT

The present invention provides an organic electroluminescent element having extended life. The present invention is an organic electroluminescent element having a pair of electrodes, and an organic light-emitting layer that contains a polymer light-emitting material and is sandwiched by the pair of electrodes, the organic electroluminescent element comprising: a first nanoparticle layer containing electron-transport metal oxide nanoparticles and hole-transport metal oxide nanoparticles, between the organic light-emitting layer and one of the pair of electrodes; and a second nanoparticle layer containing electron-transport metal oxide nanoparticles and hole-transport metal oxide nanoparticles, between the organic light-emitting layer and the other of the pair of electrodes.

### TECHNICAL FIELD

The present invention relates to an organic electroluminescent element. More specifically, the present invention relates to an organic electroluminescent element suitable as an organic electroluminescent element that can be driven by an alternating current source.

### BACKGROUND ART

An organic electroluminescent element (hereinafter also referred to as an “organic EL element”) is generally an all-solid-state light-emitting element which has a pair of the electrodes of an anode and a cathode, and an organic light-emitting layer (hereinafter also referred to simply as “light-emitting layer”) sandwiched by the pair of electrodes. Being highly visible and resistant to shocks, an organic EL element is expected to be applied in broad fields such as displays, lightings, and the like.

The production process of an organic EL element is roughly divided, based on the film forming process, into a dry process employing a method such as deposition and a wet process employing a method such as coating. The wet process allows cost reduction in the production process and an increase in the area of a panel having an organic EL element.

Here, description is given to the structure of conventional organic EL elements (coating-type organic EL elements) in which a light-emitting layer is formed by coating. FIG. 8 is a cross-sectional view schematically illustrating a conventional coating-type organic EL element.

As illustrated in FIG. 8, a conventional coating-type organic EL element has a structure where an anode 12, a hole transport layer 13, a light-emitting layer (organic light-emitting layer) 14, and a cathode 16, made of an active metal and an inert metal, are stacked on a substrate 1 in the stated order.

Such a conventional coating-type organic EL element is usually produced through the following processes. First, a solution prepared by dissolving a hole transport material in a solvent is applied on the anode 12. Next, the solvent is removed to leave the hole transport layer 13, and then the hole transport layer 13 is coated with a solution prepared by dissolving a polymer light-emitting material in a solvent that does not dissolve the hole transport material. Thereafter, the solvent is removed to leave the light-emitting layer 14, and then an active metal such as Ca and Ba and an inert metal such as Al and Ag serving as a sealing metal are deposited on the light-emitting layer 14 in the stated order so that the cathode 16 is formed.

Meanwhile, with respect to optical devices, Patent Document 1, for example, discloses an optical device having a layer made of an organic material in which light transmissive nanoparticles are dispersed in a substantially uniform manner. [Patent Document 1]

Japanese Kokai Publication No. 2002-520683

### DISCLOSURE OF INVENTION

The characteristics of conventional coating-types organic EL elements are improved as the material technologies develop. However, the conventional coating-type organic EL elements have a short element life, compared with display elements used for other flat-panel displays such as a liquid crystal display device.

The present invention was made in view of the above-mentioned state of the art. The present invention aims to provide an organic electroluminescent element having extended life.

The present inventor made various investigations on organic electroluminescent elements that can have extended life. First, the present inventor noted a light-emitting region actually emitting light in a light-emitting layer (particularly a region in which recombination of electrons and holes occurs at a high probability in the actual light-emitting region, i.e., a part (or plane) which emits most intense light, is defined herein as an emission center). That is, within a conventional coating-type organic EL element having a thickness of about 70 to 100 nm, the light-emitting region actually emitting light is considered to have a thickness of about 10 to 20 nm. The inventor noted that expanding the light-emitting region even a little or providing multiple emission centers could extend the element life. Also, use of metal oxide nanoparticles as a material for injecting and/or transporting charges was noted.

Accordingly, the inventor made further investigations. As a result, an organic electroluminescent element was found to be able to cause efficient charge injection and transportation, regardless of the material of electrodes when having the following layers: a first nanoparticle layer containing electron-transport metal oxide nanoparticles and hole-transport metal oxide nanoparticles, which is arranged between one of a pair of electrodes and a light-emitting layer (organic light-emitting layer); and a second nanoparticle layer containing electron-transport metal oxide nanoparticles and hole-transport metal oxide nanoparticles, which is arranged between the other of the pair of electrodes and the light-emitting layer (organic light-emitting layer). These first nanoparticle layer and second nanoparticle layer were found to be able to admirably solve the above problem, whereby the present invention has been completed.

That is, the present invention is an organic electroluminescent element (organic EL element) having a pair of electrodes, and an organic light-emitting layer that contains a polymer light-emitting material and is sandwiched by the pair of electrodes, the organic electroluminescent element comprising: a first nanoparticle layer containing electron-transport metal oxide nanoparticles and hole-transport metal oxide nanoparticles, between the organic light-emitting layer and one of the pair of electrodes; and a second nanoparticle layer containing electron-transport metal oxide nanoparticles and hole-transport metal oxide nanoparticles, between the organic light-emitting layer and the other of the pair of electrodes. Thereby, the life of an organic EL element can be extended.

The configuration of the organic EL element of the present invention is not specifically limited as long as the element includes the above components, and may or may not include other components.

Detailed description is given to the present invention below, and preferable embodiments of the organic EL element of the present invention are also described in detail. Note that the various embodiments below may be appropriately combined.

First, the effects of the organic EL element of the present invention are described.

When electron-transport metal oxide nanoparticles and hole-transport metal oxide nanoparticles are contained in one layer, the one layer (first nanoparticle layer or second nanoparticle layer) can efficiently transport both charges of electrons and holes, and can efficiently inject electrons and holes into a light-emitting layer. That is, the above first nanoparticle layer and the second nanoparticle layer each can function as an electron transport layer and/or an electron injection layer, and also can function as a hole transport layer and/or hole transport layer. Further, when such metal oxide nanoparticles are used, the charge transport process of the internal charges plays a major role in transportation and/or injection of charges. This means that the kind (material) of the electrode adjacent to the first nanoparticle layer or the second nanoparticle layer does not largely affect injection characteristics and transport characteristics. That is, in the organic EL element of the present invention which has the structure having a light-emitting layer sandwiched by a pair of nanoparticle layers, namely the first nanoparticle layer and the second nanoparticle layer, and electrodes sandwiching these nanoparticle layers, the direction of current flowing between the pair of electrodes can determine the injection direction of charges into the light-emitting layer. That is, for example, when the organic EL element of the present invention is driven by an AC source, it appears that electrons and holes can be injected into the light-emitting layer in either electric field direction, and the electrons and holes are recombined in the light-emitting layer to emit light.

Further, the light-emitting region in the light-emitting layer is mainly determined by the balance of transportation of electrons and holes. That is, in the conventional organic EL element, the emission center is formed in the vicinity of an interface of a hole transport layer 13 when a light-emitting material flowing electrons more easily is used, or in the vicinity of an interface of a cathode 16 when the light-emitting material flowing holes more easily is used.

Accordingly, when the direction of the electric field applied between the pair of electrodes is changed in the organic EL element of the present invention, the position of the emission center in the light-emitting layer can be changed based on the injection condition from the first nanoparticle layer and the second nanoparticle layer, how charges are flowed in the light-emitting layer, and the like.

For example, when driven by an AC source, a common conventional organic EL element can emit light in the electric field direction for light emission (forward bias), but cannot emit light in the reverse electric field direction (reverse bias).

Therefore, when a common conventional organic EL element is aged with a constant direct current (DC) source, DC continues to flow within the light-emitting layer in the forward bias direction and the emission center in the light-emitting layer is fixed in a certain part, i.e., only a certain fixed part in the light-emitting layer continues to emit light. As the element is continuously aged, the light-emitting material in this emission center deteriorates intensively and, as a result, emission luminance is easily decreased.

In contrast, when the organic EL element of the present invention is driven by a constant current source, an alternating current (AC) electric field can be applied. Further, the above emission mechanism enables the organic EL element of the present invention to change the emission position in the light-emitting layer according to the direction of the electric field applied to the pair of electrodes. Of course, the organic EL element of the present invention can provide a certain luminance in each electric field direction. That is, at least two emission centers can be formed in the light-emitting layer. As a result, the time taken for emission luminance to decrease can theoretically be at least doubled.

Further, the stress due to application of a DC electric field to the light-emitting layer only in one direction, i.e., the stress on the light-emitting layer due to charges, is considered as an indirect cause of deterioration of the element. In contrast, the organic EL element of the present invention, when driven by an AC source, can eliminate the stress due to permanent electric field application as described above, whereby deterioration of the element can be further suppressed.

As above, the organic EL element of the present invention is preferably driven by an alternating current source an AC drive).

Hence, with multiple emission centers, the organic EL element of the present invention theoretically can at least double the time taken for emission luminance to decrease, and can eliminate the stress due to a DC electric field, thereby further extending the element life, specifically to equal to or more than double the element life.

Note that the AC drive means a drive that applies an alternating current between the pair of electrodes, and the frequency of the AC drive is not specifically limited. That is, when the organic EL element of the present invention is driven by an AC source, the electric field direction may be changed at a level as low as 1 Hz, or may be changed at 60 Hz or higher; in either way, the element life can be similarly extended. However, an AC drive with a certain frequency (preferably 60 Hz) or higher is considered to provide a larger effect of preventing the degradation due to the stress caused by charges. Further, an AC drive with a certain frequency or higher can improve visibility more, as described below. Of course, permanent light emission may be possible also with a DC electric field by making the element emit light fully in one electric field direction and then reversing the electric field direction to make the element emit light in a different emission center. This also makes it possible to extend the element life compared with conventional organic EL elements.

Although the metal oxide nanoparticles in the present invention have the function to inject and/or transport charges, a firm principle is not yet established for the mechanism of injection and/or transportation of charges by the metal oxide nanoparticles in the present invention. The mechanism in the present invention, however, is considered to differ from the mechanism of electron injection and/or electron transportation by layers such as an electron injection layer, an electron transport layer, and an electron injection transport layer which are used in a conventional organic EL elements produced by a dry process. However, for convenience of explanation herein, there are descriptions such as “metal oxide nanoparticles have charge (hole or electron) injection properties and/or charge (hole or electron) transport properties” and “charge-(hole- or electron-) injection and/or charge-(hole- or electron-) transport metal oxide nanoparticles”.

The number of the organic light-emitting layers is not specifically limited as long as at least one light-emitting layer is provided.

Further, in each of the first nanoparticle layer and the second nanoparticle layer, the numbers of the kinds of respective electron-transport metal oxide nanoparticles and hole-transport metal oxide nanoparticles are not specifically limited as long as at least one kind of metal oxide nanoparticles is contained.

In the following, description is given to various preferable embodiments for achieving the effect of the present invention more effectively. First, an embodiment for effectively isolating (separating) an emission center in a light-emitting layer is described.

In order to separate an emission center in a light-emitting layer as described above, the light-emitting layer preferably has an electron transport property and a hole transport property the transport characteristics of which are different. That is, the organic light-emitting layer preferably has an electron transport property and a hole transport property which are different in transport performance. A light-emitting layer has an electron transport property and a hole transport property in some form, and a larger difference between the transport characteristics leads to a larger change in the emission center position according to the electric field direction. For example, consider a case that the light-emitting layer has a higher electron transport property than a hole transport property (electron transport property>hole transport property), and the upper side of the element is negatively charged and the lower side is positively charged. The emission center in this case is formed on the lower side of the light-emitting layer. In contrast, application of the electric field in the reverse direction leads to formation of an emission center on the upper side of the light-emitting layer. That is, when the hole and electron injection directions to the light-emitting layer are reversed, the position of the emission center in the light-emitting layer greatly changes. If two emission centers are formed without overlapping each other in the light-emitting layer, emission characteristics in the respective emission centers can be effectively provided, whereby the life can be improved more efficiently.

For the above reasons, it is preferable that the organic electroluminescent element emit light in multiple emission centers (at least two emission centers) in the organic light-emitting layer. That is, the organic electroluminescent element preferably has multiple emission centers in the organic light-emitting layer. Note that an emission center usually means a region in which recombination of electrons and holes occurs most actively, in the thickness direction of the light-emitting layer.

The organic light-emitting layer more preferably has an electron transport property and a hole transport property which are different by ten times or more in transport performance. This can almost limit the position of the emission center to the interfaces between the light-emitting layer and the first nanoparticle layer, or between the light-emitting layer and the second nanoparticle layer. That is, the position of the emission center can be set to the upper end side or the lower end side of the light-emitting layer, based on the electric field direction. Accordingly, the difference in the emission center based on the electric field direction can be further clarified.

Further, the organic light-emitting layer preferably has a higher electron transport property than a hole transport property, and contains electron-transport metal oxide nanoparticles; or the organic light-emitting layer preferably has a higher hole transport property than an electron transport property, and contains hole-transport metal oxide nanoparticles. However, many light-emitting materials, due to the characteristics thereof, may not be able to increase the charge transport property or to differentiate the levels of an electron transport property and a hole transport property. In such a case, electron-transport metal oxide nanoparticles and hole-transport metal oxide nanoparticles can be mixed into the light-emitting layer in order to further differentiate the levels of the charge transport properties in the light-emitting layer. This increases the charge transport property of the light-emitting layer while differentiating the charge transport characteristics of the light-emitting layer. As a result, the difference in the emission center based on the electric field direction can be further clarified.

Further, the number of the kinds of the electron-transport or hole-transport metal oxide nanoparticles to be contained in the organic light-emitting layer is not specifically limited as long as at least one kind of metal oxide nanoparticles is provided.

Further, an injection amount of holes being injected into the organic light-emitting layer from one side of the pair of electrodes is preferably different from an injection amount of electrons being injected into the organic light-emitting layer from the other side of the pair of electrodes. However, many light-emitting materials, due to the characteristics thereof, may not be able to increase the charge transport property or to differentiate the levels of an electron transport property and a hole transport property. In such a case, the light-emitting layer may not even be able to change the charge transport property of its own. In view of this, the amount of charge being injected into the light-emitting layer is controlled to differentiate the amount of charges flowing inside the light-emitting layer, i.e., the amount of electrons and holes being injected into the light-emitting layer. Of course, the organic EL element of the present invention preferably can be driven by an AC source from a viewpoint of more effective extension of the life. In this case, the first nanoparticle layer and the second nanoparticle layer themselves need to be able to efficiently inject both charges of electrons and holes into the light-emitting layer. Slightly changing the ratio of the electron and hole injection amounts of the respective first and second nanoparticle layers into the light-emitting layer makes it possible to differentiate the electron and hole transport characteristics of the light-emitting layer. As a result, the difference in the emission center based on the electric field direction can be further clarified.

As above, the first nanoparticle layer and the second nanoparticle layer each preferably inject holes and electrons the amounts of which are different from each other, into the organic light-emitting layer. Further, in the organic electroluminescent element, the injection amounts of holes and electrons being injected into the organic light-emitting layer are preferably different.

Next, description is given to a preferable embodiment of metal oxide nanoparticles which function also as a charge transport material.

At least one of the first nanoparticle layer and the second nanoparticle layer may be made of electron-transport metal oxide nanoparticles and hole-transport metal oxide nanoparticles, or at least one of the first nanoparticle layer and the second nanoparticle layer may contain electron-transport metal oxide nanoparticles, hole-transport metal oxide nanoparticles, and a polymer support (polymer material). Note that, in the latter, both the first nanoparticle layer and the second nanoparticle layer preferably contain electron-transport metal oxide nanoparticles, hole-transport metal oxide nanoparticles, and a polymer support (polymer material).

A metal oxide nanoparticle usually has a modifying layer of about a few nm on the surface of the particle and, as a result, metal oxide nanoparticles alone usually can be fixed to form a film by their self supporting properties. However, since this fixing force is small, many of films consisting only of metal oxide nanoparticles tend to peel off easily. Accordingly, a polymer material usually having high self supporting properties is combined with a metal oxide nanoparticle material so that the fixing forces of the first nanoparticle layer and the second nanoparticle layer can be improved and metal oxide nanoparticles can be more firmly fixed in the element. The organic EL element of the present invention needs to provide both electron transport property and hole transport property to the first nanoparticle layer and the second nanoparticle layer, and therefore needs to contain multiple kinds of metal oxide nanoparticles different in characteristics. As described above, blending multiple kinds of metal oxide nanoparticles different in characteristics into a polymer support (binder resin) makes it possible to more effectively achieve both charge properties. Such use of a polymer material as a binder leads to excellent film formation properties and to dispersion of metal oxide nanoparticles in a substantially uniform manner, and thereby a stable film can be easily formed on a light-emitting layer, an electrode, or the like.

As above, at least one of the first nanoparticle layer and the second nanoparticle layer may be a nanoparticle-containing film that contains electron-transport metal oxide nanoparticles, hole-transport metal oxide nanoparticles, and a polymer support. Alternatively, both the first nanoparticle layer and the second nanoparticle layer may be nanoparticle-containing films each containing electron-transport metal oxide nanoparticles, hole-transport metal oxide nanoparticles, and a polymer support.

Further, the number of the kinds of the polymer supports is not specifically limited as long as at least one kind of the polymer support is provided.

As a material (binder) to have metal oxide nanoparticles mixed therein, a material having a charge transport property is preferable. In this case, the binder (preferably binder resin) itself may have a charge transport property, or a material having a charge transport property may be mixed into the binder together with metal oxide nanoparticles. Examples of the material, having a charge transport property and being mixed into the binder together with metal oxide nanoparticles, include polythiophene and derivatives thereof; polypyrrole and derivatives thereof; polyaniline and derivatives thereof; and conjugated polymer materials equivalent to these materials. Although having sufficient charge transport properties, the metal oxide nanoparticles may possibly not be able to effectively transport their charges if the nanoparticles are small and the concentration of the nanoparticles dispersed uniformly in the binder is a low. Consequently, a material having charge transport properties is used as a material constituting a nanoparticle layer, as well as the metal oxide nanoparticles, so that the high charge transport properties of the metal oxide nanoparticles are more effectively extracted.

The first nanoparticle layer and the second nanoparticle layer preferably have substantially the same constitution, and have substantially the same thickness. With an AC drive, the first nanoparticle layer and the second nanoparticle layer preferably have a symmetric structure in the electric field direction, and preferably cause symmetric electric field application and charge injection into the light-emitting layer in the electric field direction. In the case that those are asymmetric in the electric field direction, the position of the light-emitting region may be biased or the stress may be applied in the biased direction, which may be a factor that accelerates degradation. For this reason, the first nanoparticle layer and the second nanoparticle layer sandwiching the light-emitting layer are made to have substantially the same constitution and substantially the same thickness so that the element can be symmetric and unbiased in the electric field direction.

Note that being substantially the same herein does not necessarily mean being exactly the same, and it is acceptable as long as being the same to the degree enabling achievement of the respective effects.

Further, a constitution preferably means either a material or a formation method, more preferably a material and a formation method, and still more preferably a material, a formation method, and a production condition. That is, the first nanoparticle layer and the second nanoparticle layer preferably contain substantially the same material or are formed by substantially the same formation method, more preferably contain substantially the same material and are formed by substantially the same formation method, and still more preferably contain substantially the same material and are formed by substantially the same formation method under substantially the same production condition.

Next, a preferable driving method of the present invention is described.

As described above, the organic electroluminescent element is preferably driven by an alternating current source. An alternating current drive can be performed by applying an electric field to the light-emitting layer by a voltage switching unit, such as a pulse generator, capable of switching positive and negative voltages. Further, this makes it possible to apply any pulses such as square waves, pulse waves with a duty cycle, and sine waves.

In this case, the organic electroluminescent element is preferably driven by an alternating current source with a driving frequency of 60 Hz or higher. With a low driving frequency of the AC drive, a decrease in the luminance may be clearly recognized when the electric field is changed. Accordingly, the organic EL element of the present invention is driven with a driving frequency of 60 Hz or higher so that the decrease in the luminance is hardly recognized at the time of the change.

Further, positive and negative electric fields being applied between the pair of electrodes preferably have substantially the same duty cycle. FIGS. 6(a) and 6(b) are conceptual diagrams illustrating an example of a driving waveform in the present invention. The AC electric field suitably applicable to the organic EL element of the present invention may have a square waveform as illustrated in FIG. 6(a), or may have a pulse waveform as illustrated in FIG. 6(b). Although not illustrated, the AC electric field may suitably have a curved waveform such as a sine curve. With such an electric field configuration, the loads on the element from positive and negative electric fields can be substantially the same, and therefore the degree of degradation or stress by positive and negative electric fields can be substantially the same. As a result, the element life can be further extended.

As above, positive and negative electric fields being applied between the pair of electrodes may provide substantially the same effective electric field. Note that positive and negative electric fields providing substantially the same effective electric field means that the positive and negative electric fields required to have the organic EL element emit light at a certain luminance during a certain selection period are substantially the same. For example, in an AC electric field, maintaining a constant voltage level and pulse width makes it possible to provide substantially the same effective electric field for positive and negative electric fields. Further, voltage levels may be different in an AC electric field as long as the emission brightness during a certain selection period can be constant by adjusting the pulse width. That is, even when the voltage levels are different in an AC electric field, the effective electric fields of the respective positive and negative electric fields can be made substantially the same by adjusting the pulse width so that the emission brightness during a certain selection period can be constant.

Alternatively, positive and negative electric fields being applied between the pair of electrodes may be different in duty cycle. Essentially, the effective electric fields of the respective positive and negative electric fields are preferably made the same as described above. Further, the structure of the organic EL element of the present invention is a solid. However, slight characteristic differences may arise, or the characteristics of interfaces between one of the nanoparticle layers and the light-emitting layer formed thereon (for example by coating) and between the light-emitting layer and the other of the nanoparticle layers formed thereon (for example by coating) may differ even when the interfaces have the same constitution in the organic EL element of the present invention having a symmetric structure in the electric field direction. In such a case, the characteristic differences between the interfaces can be resolved by changing the driving condition of the positive and negative electric fields.

As above, the effective electric fields of the respective positive and negative electric fields applied between the pair of electrodes may be different.

Next, a preferable production method of the organic EL element of the present invention is described.

At least one of the first nanoparticle layer, the second nanoparticle layer, and the organic light-emitting layer is preferably formed by spraying, and all of the first nanoparticle layer, the second nanoparticle layer, and the organic light-emitting layer are more preferably formed by spraying. Either one of the first nanoparticle layer and the second nanoparticle layer is formed on the upper layer side than the light-emitting layer (the opposite side of the substrate). At this time, a light-emitting material soluble in an organic solvent is usually used. Accordingly, for example, if a solution prepared by dispersing metal oxide nanoparticles in an organic solvent is dropped onto the light-emitting layer by a method such as spin coating or an ink jet process, the solution and the light-emitting layer may possibly be mixed and unable to form a stacked structure, and the evenness of the surface may be greatly spoiled. To avoid this, spray coating is employed to form a stacked film. Spraying is a method of forming a film by spraying a solution in a micro mist state. Therefore, the solvent is almost evaporated when the mist is applied onto the substrate, and a nanoparticle layer gets hardly mixed with the light-emitting layer when formed on the light-emitting layer. For this reason, a high-performance organic EL element having a stacked structure with secured functionality can be produced. Further, the same organic solvent as that used in formation of the light-emitting layer can be used in formation of the first nanoparticle layer and the second nanoparticle layer.

Next, another preferable embodiment of the organic EL element of the present invention is described.

The pair of electrodes may be transparent, and the organic electroluminescent element may have a light absorbing layer on an outer side of one of the pair of electrodes. In the case that one of the pair of electrodes is a transparent electrode and the other of the pair of electrodes is a reflecting electrode as in a conventional organic EL element, light interference may occur due to generation of a difference in the light path lengths of light emitted from the light-emitting layer directly to the outside and reflected light being reflected in the reflecting electrode after emitted from the light-emitting layer toward the reflecting electrode side. As a result, color purity may be deteriorated, or optical interference having angle dependence may consequently produce viewing angle characteristics of an emission color. For this reason, a light absorbing layer is provided as described above to absorb the light emitted toward the opposite side of the light-emitting surface and to effectively suppress generation of light interference, so that the above problem can be prevented.

The absorption coefficient of the light absorbing layer is not specifically limited and can be appropriately set as long as the above effect can be achieved. The characteristics of the above light absorbing layer are preferably set according to the color of the emission light of the light-emitting layer. Also, the light-emitting layer preferably has absorption characteristics for the wavelength within a visible light region, namely of about 400 to 700 nm. Such characteristics enable more effective achievement of the above effects.

A device to employ the organic EL element of the present invention is not specifically limited, and the organic EL element of the present invention can be suitably used for various devices, particularly display devices and lightings.

### EFFECT OF THE INVENTION

According to the organic EL element of the present invention, the life of the element can be extended.

### BEST MODES FOR CARRYING OUT THE INVENTION

The present invention is described in more detail based on the following embodiments with reference to the drawings. The present invention is not limited to these embodiments. The members with the same reference numerals in the following respective embodiments are formed by the same process unless otherwise explained.

### Embodiment 1

FIG. 1 is a schematic cross-sectional view of an organic EL element of Embodiment 1. The organic EL element of the present embodiment has a structure where a first electrode 2, a first nanoparticle layer 3, a light-emitting layer (organic light-emitting layer) 4, a second nanoparticle layer 5, and a second electrode 6 are stacked on a substrate 1 in the stated order, as illustrated in FIG. 1. In the following, a production method of the organic EL element of the present embodiment is described.

As the substrate 1 in the present embodiment, a substrate having an insulating surface is preferable. Examples of such a substrate include substrates made of an inorganic material such as glass and quartz; substrates made of plastic such as polyethylene terephthalate; substrates made of ceramics such as alumina; substrates formed by coating an insulator such as SiO₂ or an organic insulating material, on a metal substrate such as aluminum or iron; and substrates formed by performing insulation process such as an anode oxidation method, on the surface of a metal substrate.

First, ITO (indium tin oxide) having a thickness of 150 nm is sputtered on the entire surface of the substrate 1, and the sputtered ITO is patterned into a desired shape and a size by photolithography so that the electrode 2 is formed. In the present embodiment, the sputtered ITO is patterned to give 2×2 mm pixels.

Examples of a material of the electrode 2, other than ITO, include metals with a high work function, such as gold (Au), platinum (Pt), and nickel (Ni); and transparent conductive materials such as IDIXO (indium oxide-indium zinc oxide; In₂O₃(ZnO)ₙ) and SnO₂.

Next, the produced stack is washed after ITO patterning. Examples of the cleaning include a method of performing ultraviolet rays (UV) ozone cleaning for 30 minutes after performing ultrasonic cleaning for 10 minutes with acetone, isopropyl alcohol (IPA), or the like.

Next, a mixture is prepared by mixing barium titanate nanoparticles (electron-transport metal oxide nanoparticles) and copper oxide (Cu₂O) nanoparticles (hole-transport metal oxide nanoparticles) into polystyrene (binder resin) such that the weight ratio will be 3:1:1 (polystyrene:barium titanate:copper oxide=3:1:1). The mixture is then dissolved and/or dispersed in a mixed solvent of xylene and tetradecane to produce a solution with a solid content of 20%. Then, the solution is applied on the electrode 2 so that a nanoparticle layer (nanoparticle-containing film) 3 having a thickness of 200 nm is formed. Here, the solution is applied under the following condition: an N₂ flow of 10 l/min; a solution flow of 0.2 l/min; a spray nozzle-moving speed of 2 mm/sec; and a nozzle height of 130 cm. Thereafter, the solvent is evaporated by baking on a hot plate (for 10 minutes at 200° C.). The average particle diameter of each kind of the nanoparticles is 10 nm.

Next, the light-emitting layer 4 (thickness: 80 nm, for example) in the present embodiment is produced by the method described below. First, a coating liquid for light-emitting layer formation was produced by dissolving a polymer light-emitting material in xylene. As with the nanoparticle layer 3, the coating liquid for light-emitting layer formation is then applied to the surface of the nanoparticie layer 3 by spraying. Thereafter, the coating liquid is heat-dried in high-purity nitrogen atmosphere, so that the solvent in the coating liquid is removed. Thereby, the light-emitting layer 4 is formed.

More specifically, the light-emitting layer 4 is formed by heat-drying the coating liquid prepared by dissolving a fluorene green emission material A in xylene, at a baking temperature of 150° C. The fluorene green emission material A is a copolymer compound of a fluorene ring having alkyl chains R and R′, and at least one unit Ar (Ar′) of an aromatic aryl compound, and the chemical formula thereof is represented by the following formula (A). The fluorene green emission material A has a molecular weight of hundreds of thousands, and has a glass transition point that differs according to the unit to be copolymerized.

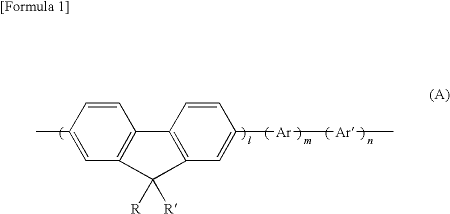

In the above formula (A), each of R and R′ represents an alkyl chain; each of Ar and Ar′ represents a unit of an aromatic aryl compound; each of 1 and in is an integer of 1 or greater; and n is an integer of 0 or 1 or greater. Examples of the aromatic aryl compound include dimethylbenzene, pyridine, benzene, anthracene, spirobifluorene, carbazole unit, benzo amine, bipyridine, and benzothiadiazole.

Further, the light-emitting material A is found to flow about 100 times or more as many holes as electrons, according to evaluation by a single carrier device.

Here, a method of measuring the difference in flow of electrons and holes is described. FIG. 2 is a cross-sectional view illustrating the configuration of a common bipolar device. FIGS. 3(a) and 3(b) are cross-sectional views illustrating the structure of a single carrier device according to the present embodiment.

As illustrated in FIG. 2, a general light-emitting element has a structure in which, for example, an ITO (thickness: 150 nm) 2a/PEDOT-PSS (thickness: 50 nm) 3/a/LEP (Light Emitting Polymer, thickness: 80 nm) 4a/Ba (thickness: 5 nm) 6a/Al (thickness: 100 nm) 6 a are stacked on a glass substrate 1a.

For comparison, an EOD (electron only device) which is an element being able to flow only electrons as illustrated in FIG. 3(a), and a HOD (hole only device) which is an element being able to flow only holes as illustrated in FIG. 3(b) are produced, and the current flow in each element is measured.

The structures of the EOD and the HOD used for measurement are shown below, and both of those were formed on the glass substrate 1a.

HOD: ITO (thickness: 150 nm) 2a/PEDOT-PSS (thickness: 60 nm) 3a/LEP (thickness: 80 nm) 4a/Au (thickness: 100 nm) 6c

EOD: ITO (thickness: 150 nm) 2a/Ca (thickness: 50 nm) 6d /LEP (thickness: 80 nm) 4a/Ba (thickness: 5 nm) 6a/aluminum (thickness: 100 nm) 6b

As above, the EOD has calcium (Ca) as the anode to prevent injection of holes into the light-emitting layer. Meanwhile, the HOD has gold (Au) as the cathode to prevent injection of electrons into the light-emitting layer.

FIG. 4 illustrates the IV characteristics of the device illustrated in FIGS. 2 and 3.

As illustrated in FIG. 4, the EOD flows much more current than the HOD; for example, when a voltage of 5 V is applied, the EOD flows a current of 20 mA/cm² whereas the HOD flows a current of only 0.2 mA/cm². This shows that the EOD flows 100 times or more as much current as the HOD.

Which of the hole-transport properties and electron-transport properties the nanoparticles have may be determined by the TOF (Time Of Flight) method.

In addition to the above light-emitting materials, known light-emitting materials for organic EL elements can also be used. The light-emitting material is not specifically limited to those examples. Specifically, low-molecular light-emitting materials, polymer light-emitting materials, precursors of polymer light-emitting materials, and the like can be used, and among these, polymer light-emitting materials are preferable. The light-emitting layer 4 is preferably formed by a wet process.

Examples of the low-molecular light-emitting material include aromatic dimethylidene compounds such as 4,4′-bis(2,2′-diphenylvinyl)-biphenyl (DPVBi); oxadiazole compounds such as 5-methyl-2-[2-[4-(5-methyl-2-benzoxazolyl)phenyl]vinyl]benzooxazol; triazole derivatives such as 3-(4-biphenylyl)-4-phenyl-5-t-buthylphenyl-1,2,4-triazole (TAZ); styryl benzene compounds such as 1,4-bis(2-methyl styryl)benzene; fluorescent organic materials such as thiopyrazine dioxide derivatives, benzoquinone derivatives, naphthoquinone derivatives, anthraquinone derivatives, diphenoquinone derivatives, and fluorenone derivatives; and fluorescent organic metallic compounds such as azomethine zinc complexes and (8-hydroxyquinolinato)aluminum complexes (Alq3).

Examples of the polymer light-emitting material include fluorescent organic metallic compounds such as poly(2-decyloxy-1,4-phenylene) (DO-PPP), poly[2,5-bis-[2-(N,N,N-triethyl ammonium)ethoxy]-1,4-phenyl-alto-1,4-phenylene]dibromide (PPP-NEt₃₊), poly[2-(2′-ethylhexyloxy)-5-methoxy-1,4-phenylenevinylene] (MEH-PPV), poly[5-methoxy-(2-propanoxy sulfonide)-1,4-phenylenevinylene] (MPS-PPV), poly[2,5-bis-(hexyloxy)-1,4-phenylene-(1-cyano vinylene)] (CN-PPV), and poly(9,9-dioctylfluorene) (PDAF).

Examples of the precursors of polymer light-emitting materials include PPV precursors, PNV precursors, and PPP precursors.

Next, as with the nanoparticle layer 3, a mixture is prepared by mixing barium titanate nanoparticles (electron-transport metal oxide nanoparticles) and copper oxide (Cu₂O) nanoparticles (hole-transport metal oxide nanoparticles) into polystyrene (binder resin) such that the weight ratio will be 3:1:1 (polystyrene:barium titanate: copper oxide=3:1:1). The mixture is then dissolved and/or dispersed in a mixed solvent of xylene and tetradecane to produce a solution with a solid content of 20%. Then, the solution is applied on the electrode 2 by spraying so that a nanoparticle layer (nanoparticle-containing film) 5 having a thickness of 200 nm is formed. Thereafter, the solvent is evaporated by baking on a hot plate (for 10 minutes at 200° C.). The average particle diameter of each kind of the nanoparticles is 10 nm.

As the binder resin used for the nanoparticle layer 3 and the nanoparticie layer 5, polyimide, polycarbonate, an acrylic resin, and an inert resin can be used as well as polystyrene. In the resin, known charge-transport materials such as an electron-transport material and a hole-transport material may be mixed.

Examples of the material of metal oxide nanoparticles used for the nanoparticle layer 3 and the nanoparticle layer 5, other than the above, include electron-transport materials such as a titanium oxide (for example, TiO₂), a cerium oxide (for example, CeO₂), an yttrium oxide (for example, Y₂O₃), and a gallium oxide (Ga₂O₃); and hole-transport materials such as ITO, a copper oxide (for example, Cu₂O), a molybdenum oxide (for example, MoO₂ (3)) and a zinc oxide (for example, ZnO₂). However, one oxide can have a different charge transport property of either the electron transport property or the hole transport property according to the production method and the state of the material. For this reason, any metal oxide nanoparticles can be appropriately used regardless of the kind of the material thereof.

As above, electron-transport metal oxide nanoparticles and hole-transport metal oxide nanoparticles in each of the nanoparticle layer 3 and the nanoparticle layer 5 may be of the same material or different materials.

The number of the kinds of the metal oxide nanoparticles contained in each of the nanoparticle layer 3 and the nanoparticle layer 5 is not specifically limited, and may be appropriately set.

The average particle diameter of the metal oxide nanoparticles is not specifically limited as long as being of the order of nanometers. The average particle diameter is preferably smaller than visible light (not larger than 400 nm) in terms of transparency, is more preferably about 5 to 50 nm, and is still more preferably not larger than about 20 nm in terms of easy thickness control, i.e., improvement in thickness uniformity. Further, nanoparticles usually aggregate to form secondary particles which are aggregates. The particle diameter in this case, i.e., the particle diameter of each secondary particle is preferably smaller than the wave range (usually 400 to 700 nm) of visible light, and this can improve the transmissivity of the nanoparticle layer 5. The particle diameter of a nanoparticle can be measured by a method such as a BET measuring method.

In the present embodiment, the nanoparticle layer 3 and the nanoparticle layer 5 were arranged symmetrically upward and downward relative to the light-emitting layer 4. However, the configuration, the materials, and the production methods of the respective nanoparticle layer 3 and nanoparticle layer 5 may be different.

Next, an aluminum (Al) film is stacked on the nanoparticle layer 5 by vacuum deposition to give a thickness of 300 nm, and thereby the electrode 6 is formed. Note that the thickness of the Al film may be acceptable as long as being in the range of 100 to 500 nm.

Examples of the material of the electrode 6 other than the above material include silver (Ag), gold (Au), and molybdenum (Mo). As above, a material with not-high activity can be used as the material of the electrode 6. One criterion for selecting the material of the electrode 6 is the work function; more specifically, a metal with a work function of not less than 4 eV can be selected as the material of the electrode 6.

Lastly, sealing glass (not illustrated) is attached by UV curable resin to the substrate 1, whereby the organic EL element of the present embodiment is completed. The thus-produced organic EL element of the present embodiment is referred to as an element A.

For comparison, description is now given to the production method of the coating-type organic EL element having the conventional element structure as illustrated in FIG. 8.

First, the same substrate 11 as the element A is prepared. Then, ITO (indium tin oxide) having a thickness of 150 nm is sputtered on the entire surface of the substrate 11, and the sputtered ITO is patterned into a desired shape and a size by photolithography so that the anode 12 is formed.

Examples of the material of the anode 12, other than ITO, include metals with a high work function, such as gold (Au), platinum (Pt), and nickel (Ni); and transparent conductive materials such as IDIXO (indium oxide-indium zinc oxide; In₂O₃(ZnO)ₙ) and SnO₂.

Next, the produced stack is washed after ITO patterning. Examples of the cleaning include a method of performing ultraviolet rays (UV) ozone cleaning for 30 minutes after performing ultrasonic cleaning for 10 minutes with acetone, isopropyl alcohol (IPA), or the like.

Next, the hole transport layer 13 is formed. The hole transport material (material of the hole transport layer 13) used is PEDOT-PSSP (EDOT/PSS {Poly(ethylene-dioxythiophene)/Poly (styrenesulfonate)}). First, a coating liquid for hole transport layer formation containing the above hole transport material is applied on the surface of the anode 12 by a spin coater to provide a film with a thickness of 60 nm. Then, the substrate 11 with an electrode is heat-dried at 200° C. for 5 minutes in high-purity nitrogen atmosphere, so that the solvent (namely, water) in the coating liquid for hole transport layer formation is removed. Thereby, the hole transport layer 13 is formed.

As above, the hole transport layer 13 can be formed by a wet process, with use of a coating liquid for hole transport layer formation in which at least one kind of hole transport material is dissolved in a solvent. The coating liquid for hole transport layer formation may contain two or more kinds of hole injection transport materials. The coating liquid for hole transport layer formation may contain resin for binding, and may contain, in addition to the resin, a leveling agent, additives such as a donor and an acceptor), and the like. Examples of the resin for binding include polycarbonate and polyester. The solvent used for the coating liquid for hole transport layer formation is not specifically limited as long as being able to have a hole transport material dissolved or dispersed therein. Examples of the solvent include pure water, methanol, ethanol, THF, chloroform, xylene, and trimethylbenzene. Alternatively, the hole transport layer 13 in the present embodiment may be formed by a dry process. The hole transport layer 13 formed by a dry process also may contain additives (such as a donor and an acceptor) and the like.

The hole transport material may alternatively be a known hole transport material for organic EL elements and organic photoconductors. Examples of the known hole transport material include inorganic p-type semiconductor materials; low-molecular materials including porphyrin compounds, aromatic tertiary amine compounds such as N,N′-bis-(3-methylphenyl)-N,N′-bis-(phenyl))-benzidine (TPD) and N,N′-di(naphthalene-1-yl)-N,N′-diphenyl-benzidine (NPD), hydrazone compounds, quinacridone compounds, and styrylamine compounds; polymer materials such as polyaniline (PANT), 3,4-polyethylenedioxythiophene/polystyrene sulfonate (PEDOT/PSS), poly[triphenylamine derivative] (Poly-TPD), and polyvinyl carbazole (PVCz); and polymer material precursors such as poly(p-phenylenevinylene) precursors (Pre-PPV) and polyp-naphthalene vinylene) precursors (Pre-PNV).

Next, the light-emitting layer 14 is produced, as with the element A. Then, the substrate 11 having the light-emitting layer 14 formed thereon is fixed in a metal deposition chamber, and barium (Ba) is deposited on the surface of the light-emitting layer 14 (to give a thickness of for example 5 nm) by vacuum deposition. Subsequently, aluminum (Al) is deposited by vacuum deposition (to give a thickness of for example 300 nm). Thereby, the cathode 16 is formed.

Examples of the material of the cathode 16 other than the above material include metal electrodes formed by stacking a metal with a low work function and a stable metal, such as Ca/Al, Ce/Al, Cs/Al, or Ca/Al; metal electrodes containing a metal with a low work function, such as Ca—Al alloys, Mg—Ag alloys, and Li—Al alloys; and electrodes formed by combining an insulating layer (thin film) and a metal electrode, such as LiF/Al, LiF/Ca/Al, and BaF₂/Ba/Al.

Lastly, sealing glass (not illustrated) is attached by UV curable resin to the substrate 11, whereby a conventional coating-type organic EL element is completed. The thus-produced conventional coating-type organic EL element is referred to as an element B.

Here, description is given to the characteristics of the organic EL element A of the present embodiment, and the characteristics of the element B which is produced for comparison.

In the element A, charges can be efficiently injected into the light-emitting layer 4 regardless of the material of the electrode 2 and the electrode 6. Accordingly, the element A can emit light efficiently with both of the electric fields under a forward bias and a reverse bias.

The following reasons are considered to explain the conductivity and charge injection properties of metal oxide nanoparticles.

### (Reason 1)

Metal oxide nanoparticles form charge transfer complexes in an interface with an electrode or with an organic layer (layer containing organic compounds) forming the interface. More specifically, charge transfer complexes (metal complexes) are formed between the oxide on the metal oxide nanoparticles and the electrode, or between the metal on the metal oxide nanoparticles and organic components constituting the organic layer. For this reason, apparently, charge is carried by the charge transfer complexes into the light-emitting layer and thus electron injection is achieved even if a band gap exists between the electrode and the metal oxide nanoparticles or between the metal oxide nanoparticles and the organic layer.

### (Reason 2)

A metal oxide, although being a dielectric itself, may sometimes not be in a completely oxidized state or a part of the material may sometimes not be completely oxidized in the nanoparticulation process. The existence of such an imperfect oxide in terms of electronic materials produces superfluous electrons and holes. That is, a layer formed by forming such metal oxide nanoparticles into a film turns out to have many internal charges. Applying an electric field to this layer moves the internal charges to a counter electrode, which gives current.

As above, the element A according to the present invention injects charges regardless of the kind of the electrode, without an active metal such as Ba. In contrast, the element B of a comparative embodiment does not emit light even if a reverse bias of 20 V or more is applied.

In comparison of element characteristics, the element A shows better Iv characteristics than the element B, and thus can decrease the driving voltage.

The element A does not contain an active metal such as Ba, as the material of the electrode 6, and thus can suppress degradation of the electrode 6 due to an external factor or migration. Further, degradation due to interaction between the charge transport material (metal oxide nanoparticles) and the light-emitting layer 4 can be suppressed. Therefore, in comparison of the element lives, the element A can extend the life more than the element B when they are driven by a DC source.

Particularly when driven by an AC source, the element A can more effectively extend the life than the element B. Examples of the conditions for an AC drive include a condition in which the luminance is set to 6000 cd/m² and a constant current square wave is applied at an alternating current frequency of 10 Hz. Also, since the organic stacked film (the first nanoparticle layer 3, the light-emitting layer 4, the second nanoparticle layer 5) between the electrode 2 and the electrode 6 in the element A is formed symmetrically upward and downward, a change in the luminance due to the change of the electric field direction in the AC drive can be suppressed.

As described above, the charge transport property of the light-emitting layer 4 is that 10 times or more as many electrons as holes flow. In the configuration of the element A, the light-emitting region, i.e., the emission center, is formed in the interface between the light-emitting layer 4 and the nanoparticle layer 3 on the side of the electrode 2 made of ITO or the like in the case of the forward bias. In the case of the reverse bias, the light-emitting region, i.e., the emission center, is formed in the interface between the light-emitting layer 4 and the nanoparticle layer 5 on the side of the electrode 6 made of Al or the like. That is, two light-emitting regions (strongest light-emitting planes) during aging can be generated on the respective upper and lower sides of the light-emitting layer 4. Further, compared with the element B, the element A can also reduce the stress due to the continuous electric field which is a problem arising at the time of the DC drive. As a result, the life of the element A can be extended to twice or more the life of the element B.

Whether or not the emission centers are different in the light-emitting layer 4 may be determined by measuring the spectra of the element. Many organic EL elements generally have a thickness of a value close to an optical path length and employ a metal as an electrode material. This may produce optical interference effects between the reflecting light from a reflecting electrode and the direct light emitted directly from the light-emitting layer, whereby the spectrum may change. For example, a change of the position of the emission center within the light-emitting layer having a thickness of about 80 nm leads to a change of the optical path length causing optical interference, and this changes the spectrum. FIG. 5 is a graph showing the simulation results of the spectra of the organic EL element. More specifically, FIG. 5 shows the simulation results of the spectra of the organic EL element having a structure with ITO/PEDOT-PSS (thickness: 60 nm)/LEP (thickness: 80 nm)/Ba/Al stacked in the stated order, in the cases that the emission center is on the PEDOT-PSS side and that the emission center is on the Ba side in the light-emitting layer.

As a result, the color purity was (0.29, 0.62) when the emission center was on the PEDOT-PSS side, and the color purity changed to (0.32, 0.58) when the emission center changed to the Ba side. As above, whether or not the emission center in the present element A has changed can be determined by measuring the spectrum when an electric field is applied to the light-emitting layer 4 in each of the forward bias direction and the reverse bias direction.

Further, in the case of the AC drive, driving at an alternating current frequency of 60 Hz or higher makes it possible to suppress flickers due to the change in the electric field, to cause light emission in the same emission state as that of the DC drive, and to further extend the life.

### Embodiment 2

The organic EL element of the present embodiment has the same configuration as the organic EL element of Embodiment 1 illustrated in FIG. 1. The only difference between the present embodiment and Embodiment 1 is that the nanoparticle layer 5 is formed on the light-emitting layer 4 by spin coating. The thus-produced organic EL element of the present embodiment is referred to as an element C.

As described above, in the element C, the nanoparticle layer 5 is intentionally formed by spin coating. The solution for nanoparticle layer 5 formation is the same as the solution used in Embodiment 1. The solvent of this solution contains xylene which dissolves the light-emitting layer 4. Since the solution is applied on the light-emitting layer 4 by spin coating in the present embodiment, the upper surface (the surface on the opposite side of the substrate 1) of the light-emitting layer 4 dissolves unlike in the case of being formed by spraying as in Embodiment 1. As a result, the faces of the light-emitting layer 4 and the nanoparticle layer 5 are mixed, which leads to unevenness on the surface.

In the thus-produced element C, injection of electrons and holes is hindered by the interface between the light-emitting layer 4 and the nanoparticle layer 5 applied on the light-emitting layer 4. This slightly deteriorates the characteristics in both forward bias direction and reverse bias direction, compared with the element A.

Further, when the element C is driven by an AC source with the same bias condition in the positive and negative electric fields, deterioration in the reverse bias direction is more significant, and this increases the speed of degradation. In view of this, the application time in the forward bias direction is made longer than the application time in the reverse bias direction for example by 1.3 times in the AC drive. As a result, the life can be extended, although not as long as the element A.

As above, the element C originally has lower characteristics than the element A and therefore cannot provide the same characteristics. However, in the case that the characteristics change according to the electric field, more load can be applied in the electric field direction providing higher characteristics to reduce the load applied in the electric field direction providing lower characteristics so that the decrease in the characteristics can be suppressed to the minimum level.

### Embodiment 3

The organic EL element of the present embodiment has the same configuration as the organic EL element of Embodiment 1 illustrated in FIG. 1. The only difference between the present embodiment and Embodiment 1 is that the metal oxide nanoparticles are dispersed in the light-emitting layer 4. The thus-produced organic EL element of the present embodiment is referred to as an element D.

The material of the metal oxide nanoparticles dispersed in the light-emitting layer 4 is barium titanate as in Embodiment 1, and the weight percentage of these metal oxide nanoparticles to the light-emitting material in the light-emitting layer 4 is controlled to be 25%. The average particle diameter of these metal oxide nanoparticles is 20 nm.

The light-emitting material B, which is a material of the same kind as the light-emitting material A, is used as the light-emitting material. According to the evaluation by a single carrier device, the light-emitting material B has an electron transport property and a hole transport property which are of about the same degree. Further, the light-emitting material B shows transport performance of about 1/10 of the transport performance of the light-emitting material A. Furthermore, the life characteristics of an element produced from the light-emitting material B and having the conventional element structure are almost the same as the life characteristics of an element produced from the light-emitting material A and having the conventional element structure.

In the present embodiment, BaTiO₃ is mixed into the light-emitting material B to give a weight ratio of 25%, and the light-emitting layer 4 (thickness: 80 nm, for example) is formed by spraying.

For comparison, an element is produced from the light-emitting material B without having nanoparticles mixed therein, and this element is referred to as an element E.

Comparison of the IV characteristics of the element D and the element F shows that the driving voltage of the element can be reduced compared to the driving voltage of the element E. With regard to the characteristics in the AC drive, the element D can efficiently emit light both in the forward bias direction and the reverse bias direction. Further, the life of the element D can be extended even to the length nearly equivalent to the life of the element A.

Meanwhile, the element E has a small difference between the electron transport property and the hole transport property of the light-emitting layer 4, and thus the emission center is formed in the center of the light-emitting layer. For this reason, the emission center hardly changes even when the electric field direction changes in the AC drive. This means that the effect of extending life by the AC drive is small. As a result, the element E emits weak light and the length of life gets shorter than the element A.

In contrast, the element D has the electron-transport metal oxide nanoparticles (BaTiO₃) mixed in the light-emitting layer 4, and thus improves the electron transport property of the light-emitting layer 4. Accordingly, the emission center can be moved to the vicinity of the interfaces between the light-emitting layer 4 and the nanoparticle layer 3 and between the light-emitting layer 4 and the nanoparticle layer 5 as in the element A. As a result, the effect of extending life by the AC drive can be fully achieved.

As above, the effect of extending life can be fully achieved by mixing electron- or hole-transport metal oxide nanoparticles into the light-emitting layer 4 even in the case that a light-emitting material with originally low charge transport properties is used.

### Embodiment 4

The organic EL element of the present embodiment has the same configuration as the organic EL element of Embodiment 1 illustrated in FIG. 1. The only difference between the present embodiment and Embodiment 1 is that the ratio of the BaTiO₃ nanoparticles to the Cu₂O nanoparticles in each of the nanoparticle layer 3 and the nanoparticle layer 5 is changed. The light-emitting material B, which is a material of the same kind as the light-emitting material A, is used as the light-emitting material.

First, the nanoparticle layer 3 is formed as in Embodiment 1. That is, a mixture is prepared by mixing barium titanate nanoparticles (electron-transport metal oxide nanoparticles) and copper oxide (Cu₂O) nanoparticles (hole-transport metal oxide nanoparticles) into polystyrene (binder resin) such that the weight ratio will be 3:2:1 (polystyrene:barium titanate:copper oxide=3:2:1). The mixture is then dissolved and/or dispersed in a mixed solvent of xylene and tetradecane to produce a solution with a solid content of 20%. Then, the solution is applied on the electrode 2 by spraying so that a nanoparticle layer (nanoparticle-containing film) 3 having a thickness of 200 nm is formed. Thereafter, the solvent is evaporated by baking on a hotplate (for 10 minutes at 200° C.). The average particle diameter of each kind of the nanoparticles is 10 nm.

Also, the nanoparticle layer 5 is formed as with the nanoparticle layer 3. That is, a mixture is prepared by mixing barium titanate nanoparticles (electron-transport metal oxide nanoparticles) and copper oxide (Cu₂O) nanoparticles (hole-transport metal oxide nanoparticles) into polystyrene (binder resin) such that the weight ratio will be 3:2:1 (polystyrene:barium titanate:copper oxide=3:2:1). The mixture is then dissolved and/or dispersed in a mixed solvent of xylene and tetradecane to produce a solution with a solid content of 20%. Then, the solution is applied on the light-emitting layer 4 by spraying so that a nanoparticle layer (nanoparticle-containing film) 3 having a thickness of 200 nm is formed. Thereafter, the solvent is evaporated by baking on a hot plate (for 10 minutes at 200° C.). The average particle diameter of each kind of the nanoparticles is 10 nm.

The thus-produced organic EL element of the present embodiment is referred to as an element F.

Comparison of the IV characteristics of the element F and the element E shows that the driving voltage of the element F can be reduced compared to the driving voltage of the element E. With regard to the characteristics in the AC drive, the element F can efficiently emit light both in the forward bias direction and the reverse bias direction. Further, the life of the element F can be extended even to the length nearly equivalent to the life the element A.

As described above, the element E has a small difference between the electron transport property and the hole transport property of the light-emitting layer 4, and thus the emission center is formed in the center of the light-emitting layer. For this reason, the emission center hardly changes even when the electric field direction changes in the AC drive. This means that the effect of extending life by the AC drive is small.

In contrast, the ratio of the electron-transport metal oxide nanoparticles (BaTiO₃) and the hole-transport metal oxide nanoparticles (Cu₂O) in each of the nanoparticle layer 3 and the nanoparticle layer 5 in the element F is changed, and thus the amount of electron injection to the light-emitting layer 4 is increased. Accordingly, the emission center can be moved to the vicinity of the interfaces between the light-emitting layer 4 and the nanoparticle layer 3 and between the light-emitting layer 4 and, the nanoparticle layer 5 as in the element A. As a result, the effect of extending life by the AC drive can be fully achieved.

As above, the effect of extending life can be fully achieved by changing the charge injection efficiency from the nanoparticle layer 3 and the nanoparticle layer 5, even in the case that a light-emitting material with originally low charge transport properties is used.

### Embodiment 5

FIG. 7 is a cross-sectional view of an organic EL element of Embodiment 5. The organic EL element of the present embodiment has a structure where a light absorbing layer 7, a first electrode 2, a first nanoparticle layer 3, the light-emitting layer 4, a second nanoparticle layer 5, and a second electrode 6 are stacked on the substrate 1 in the stated order, as illustrated in FIG. 7. In the following, the production method of the organic EL element of the present embodiment is described.

First, the same substrate 1 as in Embodiment 1 is prepared, and the light absorbing layer 7 is formed. Examples of the material of the light absorbing layer 7 include blackened materials produced by dispersing black particles such as carbon black particles into resin such as acrylic resin and polyimide resin; and materials produced by dispersing RGB colors (pigment or dye) in the above resin. Each of these resins turns into black resin which exhibits a black color. In the case that such black resin is used as the material of the light absorbing layer 7, the light absorbing layer 7 can be formed by a wet process such as spin coating and bar coating. The light absorbing layer 7 preferably has a thickness of 2 μm (more preferably 3 μm) or more in order to provide sufficient light absorbing effects to the light absorbing layer 7, depending on the ratio of the absorbing components (such as the above particles or dye) in resin.

Thereafter, the electrode 2, the nanoparticle layer 3, the light-emitting layer 4, the nanoparticle layer 5, and the electrode 6 are formed as in Embodiment 1. In the present embodiment, the electrode 2 and the electrode 6 are formed from a transparent conductive material such as ITO, IDIXO, or SnO₂ by sputtering. That is, the electrode 2 and the electrode 6 in the present embodiment each are a transparent electrode.

Another effect of metal oxide nanoparticles is the buffer effects in transparent electrode formation. The metal oxide itself is stable during the process of forming a transparent electrode.

Further, the nanoparticle layer 3 and the nanoparticle layer 5 maintain charge transport properties even when having a somewhat large thickness, and also have light transparency since containing nanoparticles. Therefore, the organic EL element of the present embodiment, having the nanoparticle layer 5 deposited on the light-emitting layer 4 as in Embodiment 1 and the like, can prevent damage and can maintain transparency even when the light-emitting layer 4 is completely covered by the nanoparticle layer 5 and the electrode 6 is formed from a transparent conductive material as described above.

As above, the organic EL element of the present embodiment has the top emission structure in which the light emitted from the light-emitting layer 4 toward the substrate 1 side is absorbed by the light absorbing layer 7, and the light emission is achieved by the light directly emitted from the light-emitting layer 4 toward the electrode 6 side.

In the elements of Embodiments 1 to 4, the effect of optical interference may occur between the reflecting light from the electrode 6 and the direct light directly emitted from the light-emitting layer 4 toward the substrate 1 side as described above, which may lead to deterioration of the visual quality. In contrast, the organic EL element of the present embodiment can absorb the light emitted toward the opposite side of the light-emitting surface, i.e., the substrate 1 side, by the light absorbing layer 7. Accordingly, the organic EL element of the present embodiment can effectively suppress the light interference between the light directly emitted toward the light-emitting surface side and the light emitted toward the light absorbing layer 7 side, and thus can improve the visual quality.

Further, the electrode 6 formed by sputtering can be a dense electrode having excellent electrode performance, evenness, and, the like compared to an electrode formed by deposition. Of course, the nanoparticle layer 5 functions as a buffer layer, and this can effectively prevent this process from deteriorating the light-emitting layer 4.

The light absorbing layer 7 may be formed on the outside of the electrode 6. In this case, the organic EL element of the present embodiment has the bottom emission structure in which the light emitted from the light-emitting layer 4 toward the electrode 6 side is absorbed by the light absorbing layer 7, and the light emission is achieved by the light directly emitted from the light-emitting layer 4 toward the substrate 1 side.

The transmissivity of the electrodes 6 and 8 in the present embodiment is not specifically limited as long as it is in the range enabling the organic EL element to emit light from the electrode 6 side and/or electrode 8 side. The transmissivity is preferably not less than 80% (more preferably not less than 90%). A transmissivity of less than 80% may decrease the luminance by 20% or more when the luminance decreases, an element life gets short by a percentage of about a square of the decreased amount of the luminance. Consequently, a decrease in the luminance by 20% or more may lead to a notable decrease in the element life by 40% or more. The transmissivity can be measured with a visible light spectrometer.

The absorptivity of the light absorbing layer 7 in the present embodiment is not specifically limited as long as it is in the range enabling suppression of visual quality deterioration due to the optical interference. The absorptivity is preferably not less than 80% (more preferably not less than 90%) from a viewpoint of decreasing the interference effect.

Since the nanoparticle layer 5 can function as a buffer layer also in Embodiments 1 to 4, the electrode 6 in Embodiments 1 to 4 may also be formed by sputtering. Thereby, the organic EL elements of respective Embodiments 1 to 4 can be suitably used as an organic EL element having the top emission structure, a transparent organic EL element in which the whole element is transparent, or the like.

The present application claims priority to Patent Application No. 2007-340311 filed in Japan on Dec. 28, 2007 under the Paris Convention and provisions of national law in a designated State, the entire contents of which are hereby incorporated by reference.

### BRIEF DESCRIPTION OF DRAWINGS

FIG. 1 is a cross-sectional view of the organic EL element of Embodiment 1.

FIG. 2 is a cross-sectional view illustrating the configuration of a common bipolar device.

FIGS. 3(a) and 3(b) are cross-sectional views illustrating the structure of the single carrier device according to the present embodiment.

FIG. 4 shows the IV characteristics of the respective devices illustrated in FIGS. 2 and 3.

FIG. 5 is a graph showing the simulation results of the spectra of the organic EL element.

FIGS. 6(a) and 6(b) are conceptual diagrams each showing an example of the driving waveform in the present invention.

FIG. 7 is a cross-sectional view of the organic EL element of Embodiment 5.

FIG. 8 is a cross-sectional view schematically illustrating the conventional coating-type organic EL element.

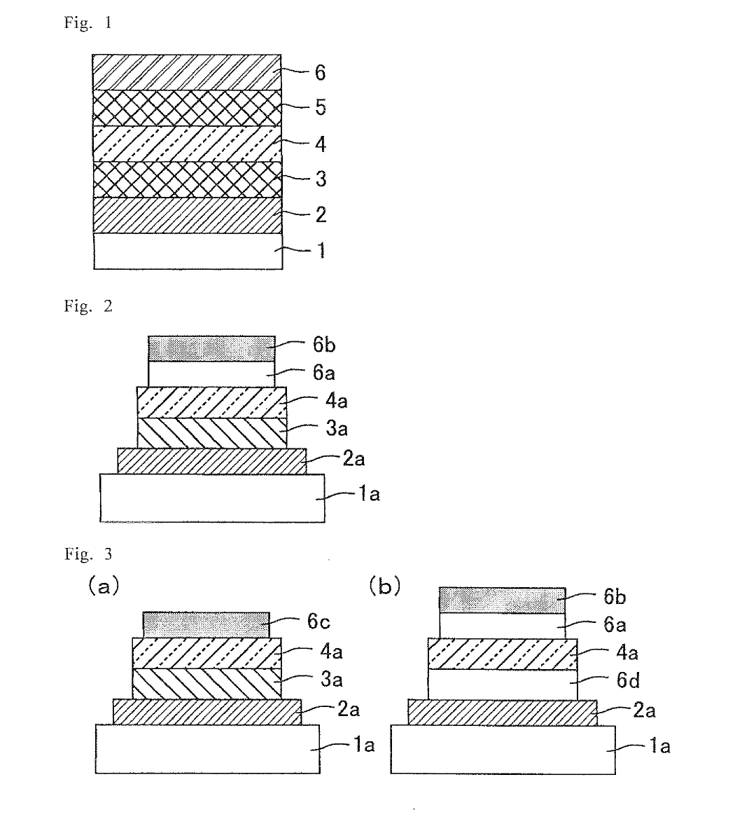

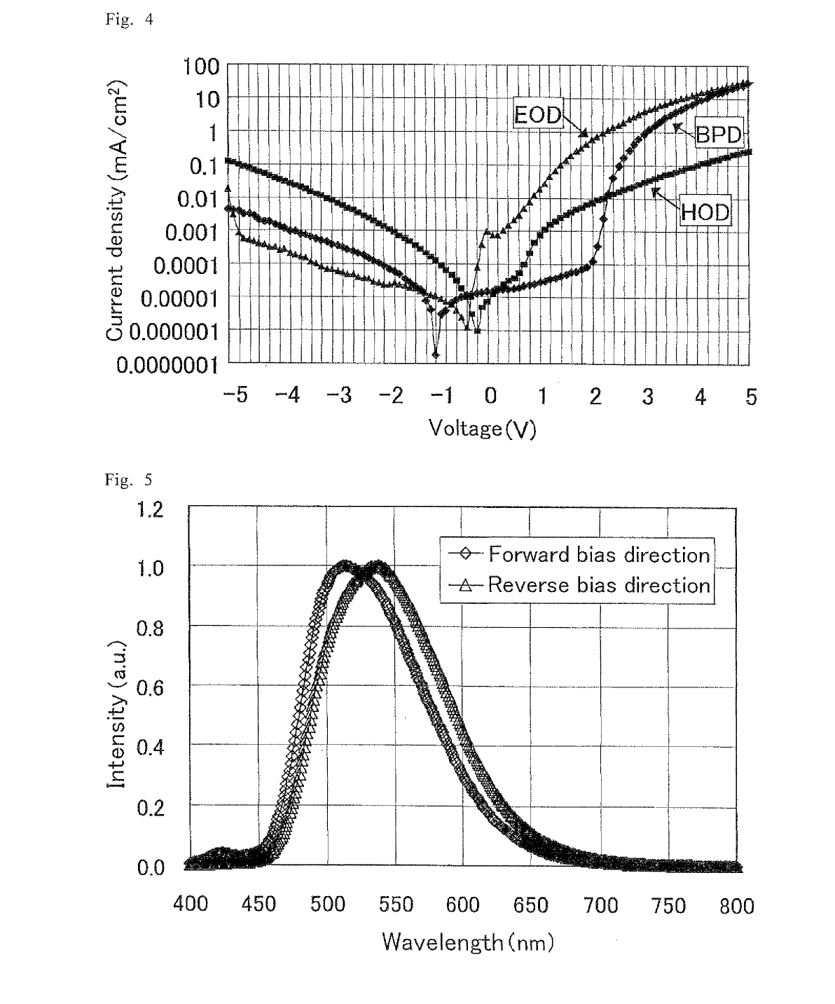

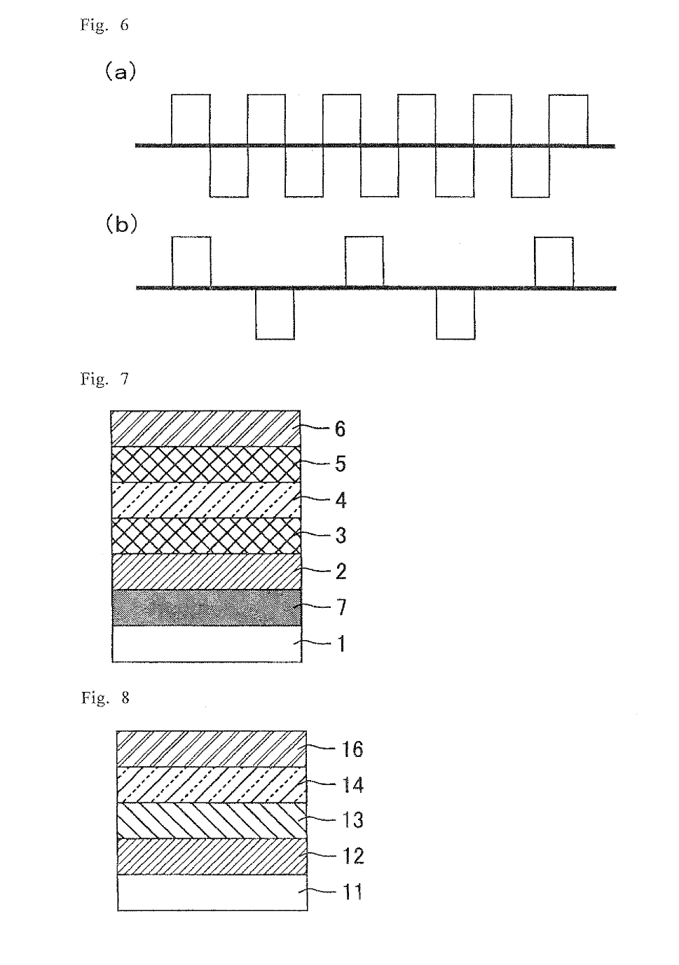

### EXPLANATION OF NUMERALS AND SYMBOLS

1, 11: Substrate
1a: Glass substrate
2, 6: Electrode
2a: ITO
3, 5: Nanoparticle layer
3a: PEDOT-PSS
4, 14: Light-emitting layer (organic light-emitting layer)
4a: LEP
6a: Vanadium (Ba)
6b: Aluminum (Al)
6c: Gold (Au)
6d: Calcium (Ca)
7: Light absorbing layer
12: Anode
13: Hole transport layer
16: Cathode

1. An organic electroluminescent element having a pair of electrodes, and an organic light-emitting layer that contains a polymer light-emitting material and is sandwiched by the pair of electrodes, the organic electroluminescent element comprising:
a first nanoparticle layer containing electron-transport metal oxide nanoparticles and hole-transport metal oxide nanoparticles, between the organic light-emitting layer and one of the pair of electrodes; and
a second nanoparticle layer containing electron-transport metal oxide nanoparticles and hole-transport metal oxide nanoparticles, between the organic light-emitting layer and the other of the pair of electrodes.

2. The organic electroluminescent element according to claim 1,
wherein the organic light-emitting layer has an electron transport property and a hole transport property which are different in transport performance.

3. The organic electroluminescent element according to claim 2,
wherein the organic light-emitting layer has an electron transport property and a hole transport property which are different by ten times or more in transport performance.

4. The organic electroluminescent element according to claim 2,
wherein the organic light-emitting layer has a higher electron transport property than a hole transport property, and contains electron-transport metal oxide nanoparticles.

5. The organic electroluminescent element according to claim 2,
wherein the organic light-emitting layer has a higher hole transport property than an electron transport property, and contains hole-transport metal oxide nanoparticles.

6. The organic electroluminescent element according to claim 1,
wherein the organic electroluminescent element has multiple emission centers in the organic light-emitting layer.

7. The organic electroluminescent element according to claim 1,
wherein at least one of the first nanoparticle layer and the second nanoparticle layer is made of electron-transport metal oxide nanoparticles and hole-transport metal oxide nanoparticles.

8. The organic electroluminescent element according to claim 1,
wherein at least one of the first nanoparticle layer and the second nanoparticle layer contains electron-transport metal oxide nanoparticles, hole-transport metal oxide nanoparticles, and a polymer support.

9. The organic electroluminescent element according to claim 1,
wherein the first nanoparticle layer and the second nanoparticle layer have substantially the same constitution, and have substantially the same thickness.

10. The organic electroluminescent element according to claim 1,
wherein an injection amount of holes being injected into the organic light-emitting layer from one side of the pair of electrodes is different from an injection amount of electrons being injected into the organic light-emitting layer from the other side of the pair of electrodes.

11. The organic electroluminescent element according to claim 1,
wherein the organic electroluminescent element is driven by an alternating current source.

12. The organic electroluminescent element according to claim 11,
wherein the organic electroluminescent element is driven by an alternating current source with a driving frequency of 60 Hz or higher.

13. The organic electroluminescent element according to claim 11,
wherein positive and negative electric fields being applied between the pair of electrodes have substantially the same duty cycle.

14. The organic electroluminescent element according to claim 11,
wherein positive and negative electric fields being applied between the pair of electrodes are different in duty cycle.

15. The organic electroluminescent element according to claim 1,
wherein at least one of the first nanoparticle layer, the second nanoparticle layer, and the organic light-emitting layer is formed by spraying.

16. The organic electroluminescent element according to claim 1,
wherein the pair of electrodes is transparent, and the organic electroluminescent element has a light absorbing layer on an outer side of one of the pair of electrodes.
